(19) United States
(12) Patent Application Publication
(10) Pub. No.: US 2025/0372733 A1
(43) Pub. Date: Dec. 4, 2025

(54) MEASUREMENT POLLING IN WIRELESS BATTERY MANAGEMENT

(71) Applicant: Analog Devices International Unlimited Company, Limerick (IE)

(72) Inventor: Lance Robert Doherty, Boston, MA (US)

(21) Appl. No.: 18/677,667

(22) Filed: May 29, 2024

(51) Int. Cl. H01M 10/42; G08C 17/02; H01M 10/48; H04B 1/713

(52) U.S. Cl. CPC H01M 10/425; G08C 17/02; H01M 10/482; H01M 2010/4271; H01M 2010/4278; H01M 2220/20; H04B 1/713

(57) ABSTRACT

Techniques for dynamically interleaving measurement data into a wireless schedule for control data communication is described herein. A dual network manager architecture can be used for interleaving upstream transmission of measurement data from battery clusters into the wireless schedule of transmitting downstream control data from the network managers.

### TECHNICAL FIELD

The present disclosure generally relates to a wireless Battery Management System (WBMS), in particular battery measurement reporting techniques.

### BACKGROUND

Electric cars have been gaining immense popularity. One factor facilitating adoption of electric vehicles has been improvement in battery management. Using a WBMS, electric cars may monitor battery levels and communicate that information to a control unit, which in turn can operate the car more reliably and efficiently. In some scenarios, the control unit may transmit control data to different battery modules at a high frequency to control battery operations. However, at the same time, the battery levels may need to be communicated.

### SUMMARY

This document describes a method for measurement polling in a wireless battery management system, the method comprising: transmitting, by a first manager, control data in a first portion of a timeslot to a plurality of battery clusters; transmitting, by a first battery cluster of the plurality of battery clusters, first measurement data in the first portion of the timeslot to a second manager; transmitting, by the second manager, the control data in a second portion of the timeslot to the plurality of battery clusters; and transmitting, by a second battery cluster of the plurality of battery clusters, second measurement data in the second portion of the timeslot to the first manager.

This document also describes a wireless battery management system comprising: a first manager to transmit control data in a first portion of a timeslot to a plurality of battery clusters; a first battery cluster of the plurality battery clusters to transmit first measurement data in the first portion of the timeslot to a second manager; the second manager to transmit the control data in a second portion of the timeslot to the plurality of battery clusters; and a second battery cluster to transmit second measurement data in the second portion of the timeslot to the first manager.

This document further describes a dual network manager comprising: at least one hardware processor; and at least one memory storing instructions that, when executed by the at least one hardware processor, cause the at least one hardware processor to perform operations comprising: a first manager transmit control data in a first portion of a timeslot to a plurality of battery clusters and to receive first measurement data from a first battery cluster of the plurality of battery clusters in a second portion of the timeslot; and a second manager to transmit the control data in the second portion of the timeslot to the plurality of battery clusters and to receive second measurement data from a second battery cluster of the plurality of battery clusters in the first portion of the timeslot.

### BRIEF DESCRIPTION OF THE DRAWINGS

Various ones of the appended drawings merely illustrate example embodiments of the present disclosure and should not be considered as limiting its scope.

FIG. 1 illustrates a block diagram of a wireless battery management system (WBMS).

FIG. 2 illustrates a block diagram of a WBMS 200 for communicating downstream control data and upstream measurement data.

FIG. 3 illustrates an example of a timeslot for measurement polling.

FIG. 4 shows example portions of a communication schedule for measurement polling.

FIG. 5 shows example portions of a wireless packet for control data.

FIG. 6 shows examples of next transmission lists for two timeslots.

### DETAILED DESCRIPTION

As mentioned above, a control unit may transmit control data to a plurality of battery clusters. For example, some electric vehicles can use an alternating current (AC) battery system. AC battery systems can include a plurality of battery clusters (e.g., 50-150 clusters) with each cluster including switches to generate a discretized AC waveform. The clusters can also include microprocessor to run a switching algorithm and a communication link to receive control data including updates to switching timing. The updates for the switching timing may be transmitted at a high frequency (e.g., every 1 millisecond). The large amount of downstream control data may make it difficult to handle upstream measurement data, especially when the same bandwidth is used for both downstream and upstream data flows in a wireless implementation.

Techniques for dynamically interleaving measurement data into a wireless schedule for control data communication is described herein. A dual network manager architecture can be used for interleaving upstream transmission of measurement data from battery clusters into the wireless schedule of transmitting downstream control data from the network managers.

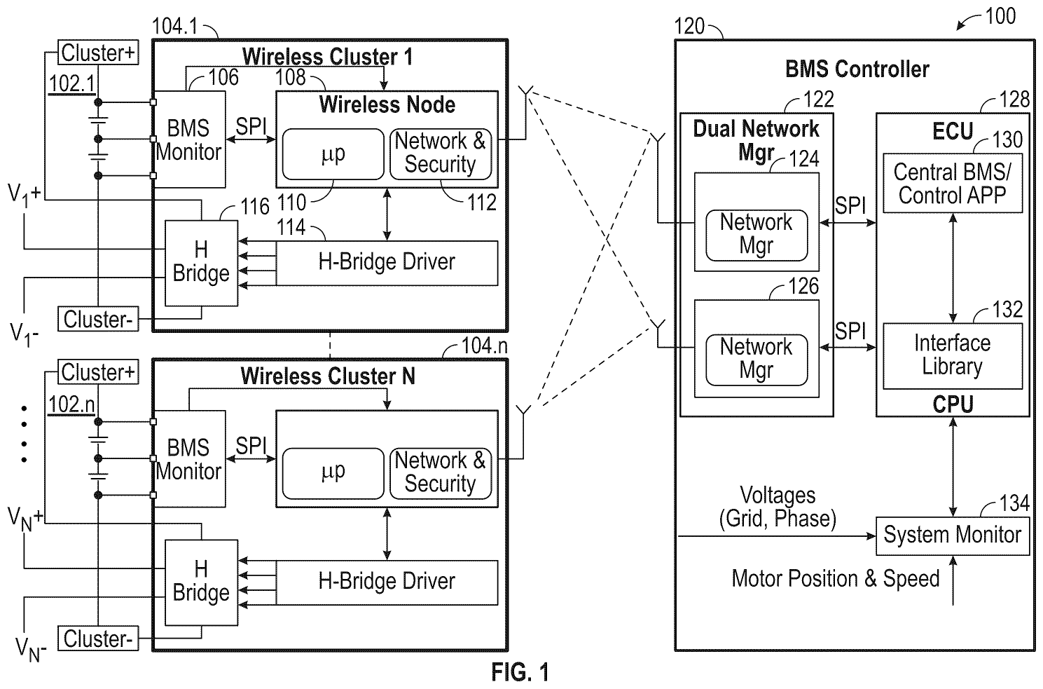

FIG. 1 illustrates a block diagram of a WBMS 100. The WBMS 100 may include a plurality of battery modules 102.1-102.n, each including a plurality of battery cells. For example, the battery modules 102.1-102.n may include high energy cells comprised of lithium-ion, sodium-ion, or solid-state materials. Batteries with different specifications, sizes, and shapes may be used. Each module may be coupled to a respective wireless cluster 104.1-104.n. The WBMS 100 may also include a BMS controller 120 with a dual network manager 122 and an Electronic Control Unit (ECU) 128.

Each cluster 104.1-104.n may include one or more BMS monitors 106 and a wireless node 108. The BMS monitor 106 may be coupled to a battery module and may monitor various conditions or properties of the battery module. The BMS monitor 106 may be provided as an integrated circuit, which can include a monolithically integrated BMS circuit or an integrated module including multiple integrated circuit die or other circuit elements within a commonly-shared integrated circuit device package, as illustrative examples.

The BMS monitor 106 may generate measurement data relating to the respective battery module 102.1-102.n. The BMS monitor 106 may include a variety of sensors. The BMS monitor 106 may sample the battery voltage to monitor the battery level. The BMS monitor 106 may also monitor current of the battery module and the external surface temperature.

The BMS monitor 106 may be coupled to the wireless node 108 by a communication interface, for example by a Serial Peripheral Interface (SPI) or the like. The BMS monitor 106 and the wireless node 108 may be provided on a single printed circuit board (PCB). The wireless node 108 may include wireless system on chip (SoC), which may include a radio transceiver to communicate with the dual network manager 122 over a wireless network.

The wireless node 108 may include a microprocessor 110 and a network and security module 112. The microprocessor 110 may run a switching algorithm based on control information received from the dual network manager 122. The wireless node 108 may include a memory (not shown) to store the switching algorithm and other information for operating the wireless node 108. The network and security module 112 may encrypt and decrypt communication between the wireless node 108 and the dual network manager 122.

The wireless clusters 104.1-104.n may include an H-bridge drive circuit 114 and a H bridge 116. The H-bridge drive circuit 114 may be coupled to the wireless node 108. For example, the microprocessor 110 may transmit H-bridge control data to the H-bridge drive circuit 114 based on the received control information from the dual network manager 122 and the switching algorithm. The H-bridge drive circuit 114 may, in turn, generate drive signals to control the H bridge 116 to provide different voltage levels (also referred to as independent states), VN+, 0, VN−. The different voltage levels may be used to generate the discretized AC waveform. A zero voltage may be provided when the respective wireless cluster is in bypass mode. For example, if a cluster does not receive control information for a time period (e.g., 5 milliseconds), the cluster may automatically transition into bypass mode as a safety measure.

Wireless clusters 104.1-104.n may communicate with each other and with the dual network manager 122 over a wireless network. The wireless network may be provided as a mesh network or the like. The wireless network may be provided using short range wireless communication networks, for example at ˜2.4 GHz, using time-synchronous channel hopping (TSCH). The dual network manager 122 may act like a central node and the wireless clusters 104.1-104.n may act like peripheral nodes. If a wireless cluster 104.1-104.n is released by the dual network manager 122 or is disconnected, it may search for a new network manager. The wireless network may be a secure network. For example, before the wireless cluster 104.1-104.n communicates with a new network manager, a secure connection may be established by using, for example, a certificate validation.

The dual network manager 122 may include a first manager 124 and a second manager 126 to communicate with the wireless clusters 104.1-104.n. The first manager 124 and second manager 126 may be provided as wireless SOCs.

The network manager 122 may be coupled to the ECU 128 via a communication interface, such as SPI. The ECU 128 may include a Central BMS/Control app 130 and interface library 132 to control operation of the WBMS 100. The ECU may be coupled to a system monitor 134. The system monitor 134 may receive vehicle and motor information, such as motor position and speed.

The ECU 128 may generate control data for operating the different wireless clusters 104.1-104.n to generate the discretized AC waveform based on the vehicle and motor information. The WBMS 100 may change the properties of the discretized AC waveform based on the current driving conditions. The frequency and amplitude of the discretized waveform (e.g., sine wave) can be adjusted based on the vehicle and motor information. For example, torque of the vehicle may correspond to a high amplitude where a large set (e.g., all) the clusters are operating, that is cycling among their positive, zero, and negative contributions in sequence. On the other hand, if the vehicle is pulling into a parking space, only a small set of clusters, such as one cluster, may be turned on for the littler power needed by the vehicle with the other clusters held in their zero voltage state. Amplitude of the AC waveform can control the torque, leading to acceleration, and frequency of the AC waveform can control the motor speed.

The dual network manager 122 may transmit the control data to the wireless clusters 104.1-104.n in a periodic manner. Indeed, the control data may be transmitted to the wireless clusters 104.1-104.n on a very frequent basis for the AC battery operation, such as every 1 millisecond. The dual network manager 122 may also receive upstream measurement data from the wireless clusters 104.1-104.n on a less frequent basis than the transmission of the control data.

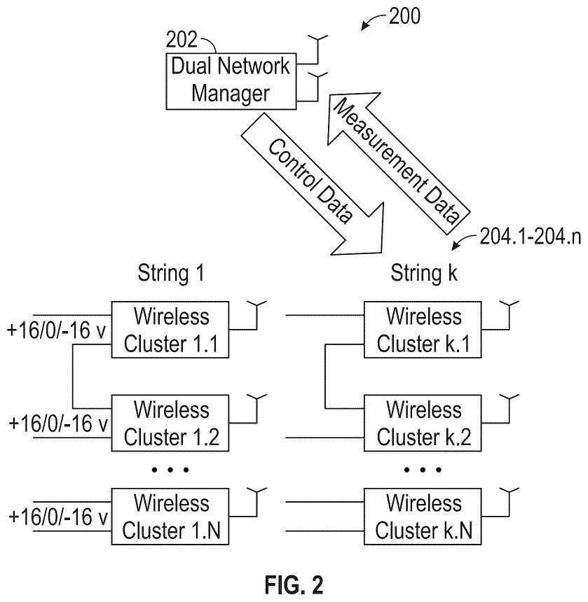

FIG. 2 illustrates a block diagram of a WBMS 200 for communicating downstream control data and upstream measurement data. The WBMS 200 includes a dual network manager 202. The WBMS 200 includes a plurality of wireless clusters 204.1-204.n arranged in strings 1-k. For example, the wireless clusters 204-1-204.n may generate a discretized AC waveform for an electric motor, such as a three-phase motor. In this case, three strings may be provided (e.g., k=3), where each string generates a discretized sine wave 120 degrees out of phase based on the control data received from the dual network manager 202. Each string may include a N number of wireless clusters. For example, each string may include eighteen wireless clusters (e.g., N=18) for a total of fifty-four clusters (e.g., n=54). In this example, the clusters may generate different voltage levels, such as +16 V, 0 V, −16 V.

The dual network manager 202 may transmit control data periodically, such as every 1 millisecond or shorter. For proper operation of the battery, the control data must reliably be received by the wireless clusters 204.1-204.n. To improve reliability, redundancy in the wireless communication may be utilized. The dual network manager 202 may transmit the same control data multiple times in the same timeslot. For example, a first manager may transmit the control data on a first channel in a first portion of a timeslot, and a second manager may transmit the same control data on a second channel in a second portion of the timeslot. In some examples, the first manager and the second manager may transmit the control data in the same portion of the timeslot on different channels, such as different frequencies of a TSCH scheme. The redundancy in the transmission of the control data may improve reliability of the communication and hence the efficiency of the battery operation.

The dual network managers 202 may also receive measurement data from respective wireless clusters 204.1-204.n. The measurement data may include property values of the coupled battery cluster, such as voltage of the individual battery cells in the cluster, the single current flowing equally through the cluster cells, and temperature measurements from external thermocouples positioned around the battery cells. The measurement data may also include diagnostic data used to confirm the validity and integrity of the property values above including measurements taken with a separate voltage reference and samples taken through alternate digitization paths. Each wireless cluster 204.1-204.n may transmit measurement data corresponding to its respective battery module to the dual network managers 202 on a less frequently than the control data. For example, if unique control data is transmitted every millisecond (e.g., two transmissions of the same control data in a millisecond timeslot), a respective wireless cluster may transmit its measurement data every 100 ms.

As mentioned above, the dual network manager 202 may transmit the same control data multiple times in the same timeslot. For example, a first manager may transmit the control data on a first channel in a first portion of a timeslot, and a second manager may transmit the same control data on a second channel in a second portion of the timeslot. The timeslot architecture may also be used for upstream measurement reporting to the dual network manager 202.

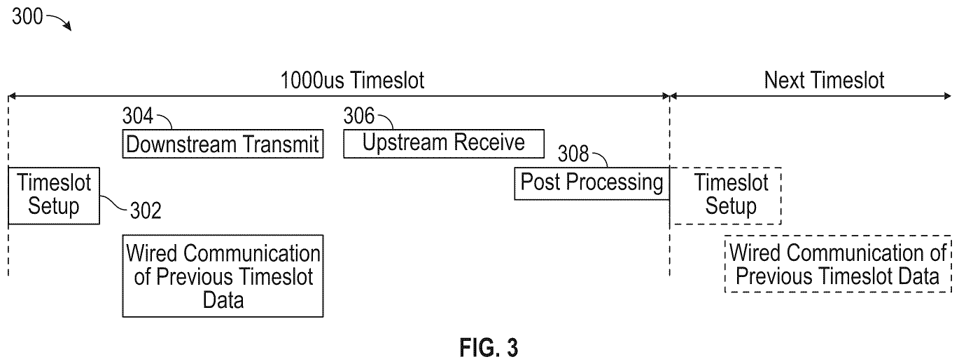

FIG. 3 illustrates an example of a timeslot 300 for measurement polling. In FIG. 3, the use of timeslot 300 is from a perspective of a first (or second) network manager of a dual network manager, as described above. In this example, the timeslot 300 is about 1 millisecond (or 1000 us); however, other durations of the timeslot can be used, such as timeslots shorter than 1 millisecond. The dual network manager may receive the control data to transmit in timeslot 300 in the previous timeslot from the ECU using a wired connection, such as SPI.

The timeslot 300 includes a timeslot setup 302 in the beginning of the timeslot. This timeslot setup 302 is shared by all other portions of the timeslot communications allowing multiple portions to be used for different communication actions. Prior to sending data in a timeslot, several steps are performed including obtaining the data to send from an external source, such as ECU 128, and powering up and configuring the transceiver. These operations for setup involve software control and hence not completely deterministic so the setup time is buffered against worst case performance. Each timeslot includes its own respective timeslot setup. Therefore, using different portions of a timeslot to communicate control data multiple times is different and more efficient than communicating the control data multiple times in successive timeslots.

The timeslot 300 includes a downstream transmit portion 304 (i.e., a first portion). The first network manager may transmit control data during the downstream transmit portion 304. During this time, wireless cluster may transmit the contents of the control data received in the previous timeslot to respective components, such as H-bridge driver or BMS monitor.

The timeslot 300 includes an upstream receive portion 306 (i.e., a second portion). The first network manager may receive measurement data from a designated wireless cluster in a specified channel in the upstream receive portion 306. As discussed in further detail below, the second network manager may transmit the control data during the second portion (i.e., upstream receive portion 306 for the first network manager) on a different channel. Therefore, redundancy in the transmission of the control data by the first and second network managers is maintained while allocating certain portions of the wireless schedule for reporting measurement data by the wireless clusters.

The timeslot 300 includes a post portion 308 for processing to prepare for communication in the next timeslot. In some examples, the post portion 300 can start during the receive portion 306. That is, once the radio components are engaged with the receive portion 306, the processor can start post processing in the post portion 308. This post processing often uses software intervention and hence may be sized appropriately for worst case timing. The next timeslot may then begin with its respective timeslot setup, as discussed above.

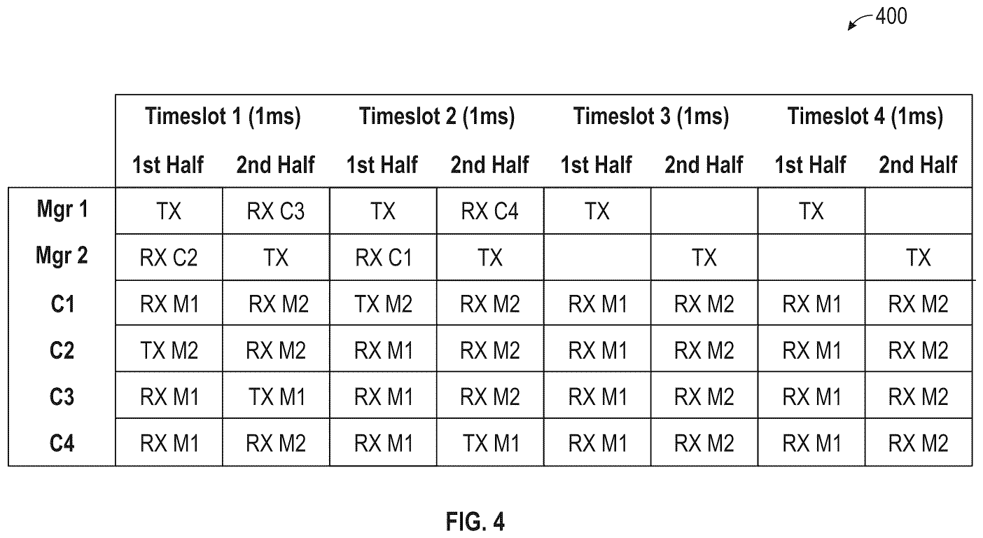

FIG. 4 shows example portions of a communication schedule 400 for measurement polling. The communication schedule shows communications for a first manager (Mgr 1), a second manager (Mgr 2), and four clusters (C1-C4) for simplicity and brevity. The schedule (and channel information) for upstream transmission by the clusters can be broadcast prior to timeslot 1. For example, the upstream transmission schedule may be transmitted to the wireless clusters in an earlier timeslot (e.g., timeslot 0). In this example, the upstream transmission schedule includes C2 transmitting its measurement data in the first portion of the first timeslot, C3 transmitting its measurement data in the second portion of the first timeslot, C1 transmitting its measurement data in the first portion of the second timeslot, and C4 transmitting its measurement data in the second portion of the second timeslot.

In the first portion (1^{st} half) of timeslot 1, Mgr1 transmits control data. For example, the Mgr1 may transmit the control data on a first channel, such as a first frequency of a TSCH scheme, to which all the clusters are listening in the first portion of timeslot 1 except for cluster 2. While clusters C1, C3, and C4 are tuned to the first channel listening to Mgr1 for the control data in the first portion of timeslot 1, cluster C2 transmits its measurement data to Mgr2 on a second channel in the first portion of the timeslot 1. Mgr2 is tuned to the second channel listening for the scheduled transmission by C2 in the first portion.

In the second portion (2^{nd} half) of timeslot 1, Mgr 2 transmits the control data, which is the same control data transmitted by Mgr 1 in first portion. For example, the Mgr 2 transmits the control data on a third channel. While clusters C1, C2, and C4 are listening to Mgr2 for the control data in the second portion of timeslot 1, cluster C3 transmits its measurement data to Mgr1 on a fourth channel in the second portion of the timeslot 1. Mgr1 is listening for the scheduled transmission by C3 in the second portion.

In the first portion (1^{st} half) of timeslot 2, Mgr1 transmits control data. For example, the Mgr1 may transmit the control data on the first channel to which all the clusters are listening in the first portion of timeslot 1 except for cluster 1. While clusters C2, C3, and C4 are listening to Mgr1 for the control data in the first portion of timeslot 2, cluster C1 transmits its measurement data to Mgr2 on a second channel in the first portion of the timeslot 2. Mgr2 is listening for the scheduled transmission by C1 in the first portion.

In the second portion (2^{nd} half) of timeslot 2, Mgr 2 transmits the control data, which is the same control data transmitted by Mgr 1 in first portion of timeslot 2. For example, the Mgr 2 transmits the control data on a third channel. While clusters C1, C2, and C3 are listening to Mgr2 for the control data in the second portion of timeslot 2, cluster C4 transmits its measurement data to Mgr1 on a fourth channel in the second portion of the timeslot 2. Mgr1 is listening for the scheduled transmission by C4 in the second portion.

Since all four clusters (C1-C4) have transmitted their measurement data in the first two timeslots and measurement data may be sent less frequency (e.g., every 100 ms), the next few timeslots may only have transmission of control data and upstream measurement data, which improves reliability of the downstream control data. The clusters get two opportunities to receive the control data in a timeslot except for the timeslot the respective cluster is scheduled to transmit its measurement data.

In the first portion of timeslot 3, Mgr 1 transmits control data to which clusters C1-C4 are listening. In the second portion of timeslot 4, Mgr 2 transmits the same control that was transmitted in the first portion of timeslot 4 to which clusters C1-C4 are listening. In some examples, the first manager and the second manager may transmit the control data in the same portion of timeslot 3 on different channels, such as different frequencies of a TSCH scheme. Timeslot 4 may operate similarly to timeslot 3.

As mentioned above, the scheduling information for cluster upstream transmission may be transmitted by the managers. The scheduling information may be dynamically updated based on successful or unsuccessful upstream transmissions. That is, if a cluster's upstream transmission is unsuccessful, the managers may re-schedule that cluster to retransmit its measurement data.

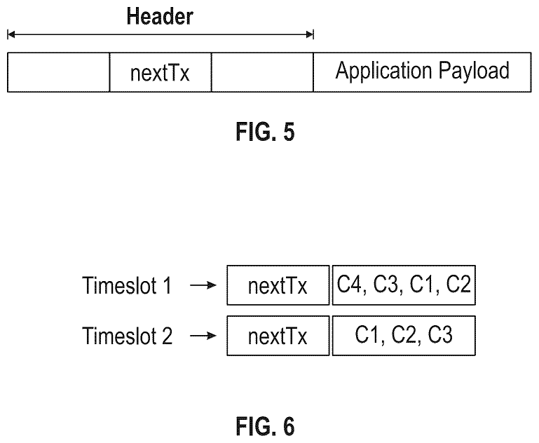

FIG. 5 shows example portions of a wireless packet 500 for control data. The wireless packet 500 may be transmitted by the first manager and second manager, as described above. The wireless packet 600 includes a header portion and application payload portion. The application payload portion may include the control data, as described above. The header portion may include a number of bytes for a next transmission list (nextTx) used to store an ordered list indicating identifiers of the clusters to transmit their respective measurement data in the upcoming timeslots.

FIG. 6 shows examples of next transmission lists for two timeslots. In this example, the dual network manager is able to poll two clusters to transmit upstream in each timeslot as described above. In the first timeslot, the nextTx list includes C4, C3, C1, and C2. The nextTx instructs C4 and C3 to transmit their respective measurement data in the next timeslot with C4 transmitting in the first portion of the timeslot and C3 in the second portion. Consider that in this example, the C4 transmission to the dual network manager succeeded in the first portion of the timeslot so C4 can be removed from the list. However, in this example, the transmission from C3 scheduled for the second portion of the timeslot has failed so the manager re-inserts it to the rear of the list. Therefore, in the second timeslot, the nextTx includes C1, C2, and the re-inserted C3.

Measurement polling, as described herein, is an efficient mechanism when fast and reliable downstream control data is used in the system. Both upstream and downstream transmissions can fail over a wireless medium. Measurement polling, as described herein, can leverage downstream update rates being faster in this application than upstream (e.g. 1 ms vs. 100 ms), meaning that the frequent downstream packets can be used to schedule the upstream data. The upstream schedule may be determined by which cluster has reported least recently if the manager is optimizing to minimize the time between any data refresh from any cluster.

The length of the nextTx field can be a tradeoff between reliability and bandwidth. A longer nextTx, such as 10 clusters in a list, gives each cluster up to 8 repetitions of its identifier in the ordered list before it needs to send its measurement data. A node's identifier first appears at the end of the list in the first manager control data, then two elements earlier in the second manager control data, and so forth until the cluster is first in the list and set to report upstream measurement data in the next timeslot. This repetition over time also gives the node the opportunity to schedule the measurement if either it takes a certain amount of time to perform the measurement or if there is value in having the measurement taken as close to the transmission as possible.

One advantage of using measurement polling is that clusters with a lower transmission success rate to the managers can be reinserted into the ordered list more frequently and hence obtain a larger share of the overall network bandwidth. This is in contrast to a statically provisioned system wherein all clusters are allocated a fixed and equal number of retries for each measurement data transmission. This strategy is effective especially when the downstream update rate is much higher than the upstream update rate.

### Various Notes

Each of the non-limiting aspects above can stand on its own or can be combined in various permutations or combinations with one or more of the other aspects or other subject matter described in this document.

The above detailed description includes references to the accompanying drawings, which form a part of the detailed description. The drawings show, by way of illustration, specific implementations in which the invention can be practiced. These implementations are also referred to generally as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other implementations can be used, such as by one of ordinary skill in the art upon reviewing the above description. The Abstract is provided to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed implementation. Thus, the following claims are hereby incorporated into the Detailed Description as examples or implementations, with each claim standing on its own as a separate implementation, and it is contemplated that such implementations can be combined with each other in various combinations or permutations. The scope of the invention should be determined with reference to the appended claims, along with the full scope of equivalents to which such claims are entitled.

1. A method for measurement polling in a wireless battery management system, the method comprising:
transmitting, by a first manager, control data in a first portion of a timeslot to a plurality of battery clusters;
transmitting, by a first battery cluster of the plurality of battery clusters, first measurement data in the first portion of the timeslot to a second manager;
transmitting, by the second manager, the control data in a second portion of the timeslot to the plurality of battery clusters; and
transmitting, by a second battery cluster of the plurality of battery clusters, second measurement data in the second portion of the timeslot to the first manager.

2. The method of claim 1, wherein the timeslot includes a timeslot setup portion shared by the first portion and the second portion.

3. The method of claim 1, wherein the first manager transmits the control data in the first portion of the first timeslot on a first channel and the first battery cluster transmits first measurement data in the first portion of the timeslot on a second channel.

4. The method of claim 3, wherein the first channel is a first frequency of a time-synchronous channel hopping (TSCH) scheme, and the second channel is a second frequency of the TSCH scheme.

5. The method of claim 1, wherein the control data transmitted by the first manager comprises an ordered list of battery cluster scheduled transmissions.

6. The method of claim 5, wherein a battery cluster specified at the beginning of the ordered list is scheduled to transmit measurement data in a next timeslot.

7. The method of claim 1, wherein the control data includes switching information for the plurality of battery clusters to generate a discretized AC waveform.

8. A wireless battery management system comprising:
a first manager to transmit control data in a first portion of a timeslot to a plurality of battery clusters;
a first battery cluster of the plurality battery clusters to transmit first measurement data in the first portion of the timeslot to a second manager;
the second manager to transmit the control data in a second portion of the timeslot to the plurality of battery clusters; and
a second battery cluster to transmit second measurement data in the second portion of the timeslot to the first manager.

9. The wireless battery management system of claim 8, wherein the timeslot includes a timeslot setup portion shared by the first portion and the second portion.

10. The wireless battery management system of claim 8, wherein the first manager to transmit the control data in the first portion of the first timeslot on a first channel and the first battery cluster to transmit first measurement data in the first portion of the timeslot on a second channel.

11. The wireless battery management system of claim 10, wherein the first channel is a first frequency of a time-synchronous channel hopping (TSCH) scheme, and the second channel is a second frequency of the TSCH scheme.

12. The wireless battery management system of claim 8, wherein the control data transmitted by the first manager comprises an ordered list of battery cluster scheduled transmissions.

13. The wireless battery management system of claim 12, wherein a battery cluster specified at the beginning of the ordered list is scheduled to transmit measurement data in a next timeslot.

14. The wireless battery management system of claim 8, wherein the control data includes switching information for the plurality of battery clusters to generate a discretized AC waveform.

15. A dual network manager comprising:
at least one hardware processor; and
at least one memory storing instructions that, when executed by the at least one hardware processor, cause the at least one hardware processor to perform operations comprising:
a first manager transmit control data in a first portion of a timeslot to a plurality of battery clusters and to receive first measurement data from a first battery cluster of the plurality of battery clusters in a second portion of the timeslot; and
a second manager to transmit the control data in the second portion of the timeslot to the plurality of battery clusters and to receive second measurement data from a second battery cluster of the plurality of battery clusters in the first portion of the timeslot.

16. The dual network manager of claim 1, wherein the timeslot includes a timeslot setup portion shared by the first portion and the second portion.

17. The dual network manager of claim 1, wherein the first manager to transmit the control data in the first portion of the first timeslot on a first channel and the first battery cluster to transmit first measurement data in the first portion of the timeslot on a second channel.

18. The dual network manager of claim 3, wherein the first channel is a first frequency of a time-synchronous channel hopping (TSCH) scheme, and the second channel is a second frequency of the TSCH scheme.

19. The dual network manager of claim 1, wherein a transmission schedule for upstream measurement polling is transmitted to the plurality of battery clusters prior to the timeslot.

20. The dual network manager of claim 1, wherein the control data includes switching information for the plurality of battery clusters to generate a discretized AC waveform.
